(19) United States
(12) Patent Application Publication
(10) Pub. No.: US 2009/0126785 A1
(43) Pub. Date: May 21, 2009

(54) SOLAR CELL MODULE

(75) Inventor: Toshio YAGIURA, Kobe City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/264,308

(22) Filed: Nov. 4, 2008

(30) Foreign Application Priority Data
Nov. 19, 2007 (JP) JP2007-299728

(51) Int. Cl. H01L 31/00

(52) U.S. Cl. 136/256

(57) ABSTRACT

An aspect of the invention provides a solar cell module that comprises: a solar cell having a light-receiving surface and a back surface formed on an opposite side to the light-receiving surface, the solar cell configured to generate electric power from light on the light-receiving surface; a translucent member covering the light-receiving surface side of the solar cell; a case covering the back surface side of the solar cell and formed integrally of a resin; and a conductive output cable buried in the case, a first end of the output cable electrically connected to the solar cell, a second end of the output cable exposed to the outside of the case, the conductive output cable comprising a locking part that locks the output cable in the case.

### CROSS REFERENCE TO RELATED APPLICATIONS

This application claims priority based on 35 USC 119 from prior Japanese Patent Application No. P2007-299728 filed on Nov. 19, 2007, entitled “Solar cell module”, the entire contents of which are incorporated herein by reference.

### BACKGROUND OF THE INVENTION

1. Field of the Invention

The present invention relates to a solar cell module having an output cable for sending electric power generated by a solar cell to an external device.

2. Description of Related Art

In general, in a solar cell module, a solar cell is sealed by a sealing member between a light-receiving surface side protecting member and a back surface side protecting member. The light-receiving surface side protecting member is made of a glass board or the like. The back surface side protecting member is made of a polyethylene terephthalate (PET) film or the like.

For example, Japanese Laid-open Patent Publication No. hei 3-116978 discloses a solar cell. A wiring member for extracting electric power generated by the solar cell is connected thereto. The wiring member passing through a sealing member is led to the exterior from an opening formed in a back surface side protecting member. A part, which is led to the exterior from the opening of the wiring member is housed in a terminal box that is attached so as to cover the opening. The wiring member in the terminal box is electrically connected to an output cable for sending the electric power generated by the solar cell to an external device.

Here, in the case where the output cable is attached to the external device, the output cable may be pulled by an external force. Therefore, it is necessary to fix the output cable to an inner wall of the terminal box with the use of a fixture so as to prevent the output cable from falling out from the terminal box.

Furthermore, in an environment where the solar cell module is used, moisture may come in from the opening formed in the back surface side protecting member. Therefore, it is necessary to tightly seal the inside of the terminal box by a sealing member to prevent outside air from entering the terminal box.

As described above, the structure for extracting electric power generated by a solar cell to the exterior of a solar cell module comprises of a large number of parts. Accordingly, complicated assembling work has been required in a production process of a solar cell module.

### SUMMARY OF THE INVENTION

An aspect of the invention provides a solar cell module that comprises: a solar cell having a light-receiving surface and a back surface formed on an opposite side to the light-receiving surface, the solar cell configured to generate electric power from light on the light-receiving surface; a translucent member covering the light-receiving surface side of the solar cell; a case covering the back surface side of the solar cell and formed integrally of a resin; and a conductive output cable buried in the case, a first end of the output cable electrically connected to the solar cell, a second end of the output cable exposed to the outside of the case, the conductive output cable comprising a locking part that locks the output cable in the case.

As described above, the output cable is directly buried in the case. Accordingly, it is not necessary to attach a terminal box or the like. Therefore, in a production process of the solar cell module, it is not necessary to perform complicated assembling work. Meanwhile, the locking part configured to lock the output cable in the case is provided to the output cable. Accordingly, even in the case where the output cable is directly buried in the case, the output cable can be strongly fixed thereto.

### BRIEF DESCRIPTION OF THE DRAWINGS

FIG. 1 is a top view illustrating a configuration of solar cell module 100 of a first embodiment.

FIG. 2 is a cross-sectional view taken along sectional line A-A of FIG. 1.

FIG. 3 is a cross-sectional view taken along sectional line B-B of FIG. 2.

FIGS. 4A and 4B are an enlarged view of a part of FIG. 3.

FIG. 5 is a view illustrating a configuration of spherical part 75 that serves as a locking part of a second embodiment.

FIG. 6 is a view illustrating a configuration of straight line part 85 that serves as a locking part of a modification example of the second embodiment.

FIG. 7 is a view illustrating a configuration of connecting terminal 95 that serves as a locking part of a third embodiment.

FIG. 8 is a view illustrating bent part 110 that serves as a locking part of a fourth embodiment.

### DETAILED DESCRIPTION OF EMBODIMENTS

Embodiments will be described below with reference to the accompanying drawings. In the following description, parts or units that are identical or similar to each other across the first and the second embodiments will be given identical or similar reference numerals.

Next, with reference to drawings, embodiments will be described.

### First Embodiment

(Schematic Configuration of a Solar Cell Module)

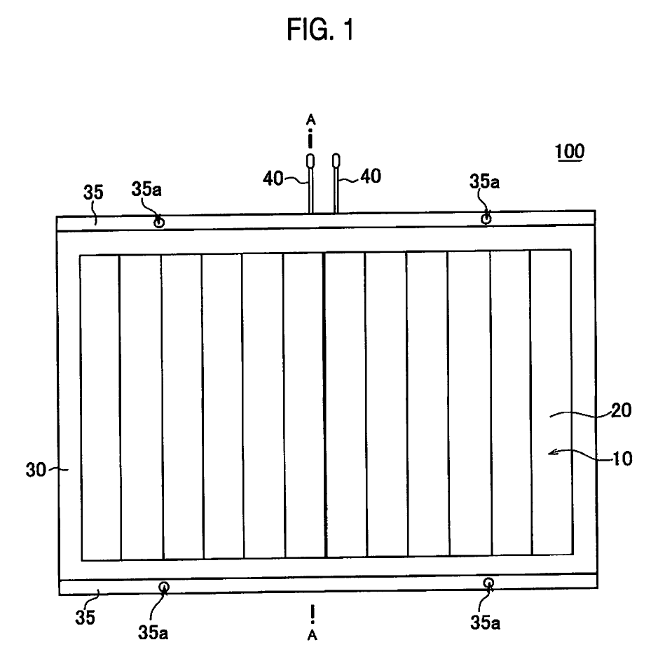

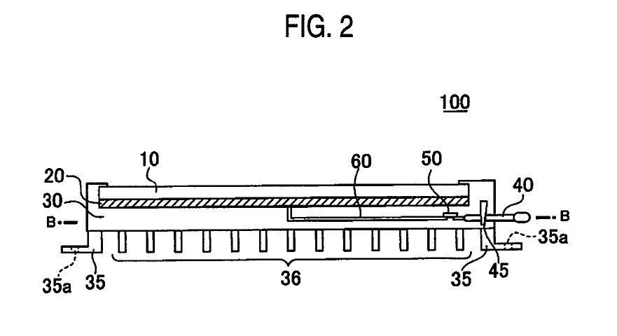

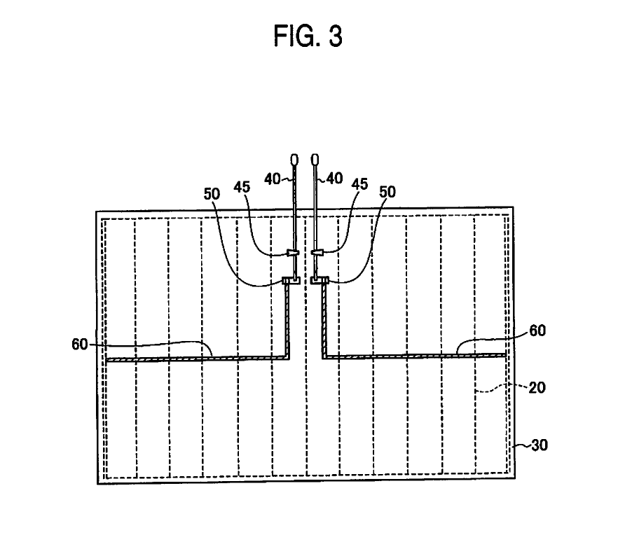

A schematic configuration of solar cell module 100 of a first embodiment will be described by referring to FIG. 1 to FIG. 3. FIG. 1 is a top view illustrating a configuration of solar cell module 100. FIG. 2 is a cross-sectional view taken along sectional line A-A of FIG. 1. FIG. 3 is a cross-sectional view taken along sectional line B-B of FIG. 2.

As shown in FIG. 1 to FIG. 3, solar cell module 100 includes: translucent member 10; solar cell 20; case 30; output cable 40; terminal block 50; and wiring member 60.

Translucent member 10 protects a light-receiving surface side of solar cell module 100. As translucent member 10, a translucent member made of glass, transparent plastic, and the like can be used. In the first embodiment, translucent member 10 may be a single substrate of solar cell 20. On a back surface of translucent member 10, a transparent conductive oxide (TCO) film is formed.

Solar cell 20 is formed on the back surface of translucent member 10 as illustrated in FIG. 2. More specifically, solar cell 20 is formed by sequentially laminating a transparent conductive oxide film, a semiconductor layer, and a back surface electrode while patterning them by a commonly-known laser patterning method. Here, solar cell 20 is an integrated solar cell composed of multiple solar cell elements which are electrically serially connected with each other.

As the semiconductor layer, for example, a laminated body of an amorphous silicon semiconductor layer and a microcrystalline silicon semiconductor layer or any one of them can be used. The amorphous silicon semiconductor layer and the microcrystalline silicon semiconductor layer each have a p-i-n semiconductor junction.

Furthermore, solar cell 20 has a light-receiving surface and a back surface that is formed on an opposite side to the light-receiving surface. The light-receiving surface of solar cell 20 is covered by translucent member 10. Solar cell 20 generates electric power by receiving solar light having passed through translucent member 10 with the light-receiving surface.

Case 30 is formed so as to go over the back surface of solar cell 20 to a side surface of translucent member 10. Case 30 can be formed uniformly by using, for example, a phenol resin, an epoxy resin, a melamine resin, a thermosetting polyimide, polyurethane, unsaturated polyester, an alkyd resin, a urea resin, an olefin resin, or the like. Here, as will be described later, case 30 may also be formed by pouring the above-described resin into a metal mold in which translucent member 10 and solar cell 20 are placed. For this reason, solar cell 20 may be sealed inside of case 30 without involving other member.

Case 30 has leg 35 as shown in FIG. 1 and FIG. 2. Leg 35 has hole 35a to which a bolt configured to fix solar cell module 100 to an installation site is to be attached. Furthermore, on a back surface of case 30, as shown in FIG. 2, multiple rib members 36 are attached for the purpose of enhancing the strength of solar cell module 100. Multiple rib members 36 are arranged along the entire length of solar cell module 100.

Output cable 40 is a cable configured to send electric power generated by solar cell 20 to an external device. Output cable 40 includes a metal core wire and an insulating film that covers the core wire. As shown in FIG. 2, output cable 40 is buried in case 30. One end of output cable 40 is soldered to terminal block 50. The other end of output cable 40 is exposed to the outside of case 30. To the other end of output cable 40, a connecting terminal to be connected to an external device is attached.

Here, as shown in FIG. 2, fixture 45 (locking part) is attached to output cable 40. Fixture 45 protrudes from the outer periphery of output cable 40.

Terminal block 50 is a conductive material configured to electrically connect output cable 40 and wiring member 60. Terminal block 50 is buried in case 30.

Wiring member 60 is a conductive material configured to extract electric power generated by solar cell 20 from solar cell 20. As wiring member 60, copper or the like formed in a thin plate shape, a line shape, or a twisted-line shape can be used. As shown in FIG. 2 and FIG. 3, one end of wiring member 60 is soldered to both ends of solar cell 20. The other end of wiring member 60 is soldered to terminal block 50. By having such a configuration, electric power generated by solar cell 20 is extracted to the outside of solar cell module 100 through output cable 40. Wiring member 60 is buried in case 30. Here, it is preferable that insulation treatment be provided to the outer periphery of wiring member 60.

Furthermore, in the first embodiment, as described above, electric power generated by solar cell 20 is sent to output cable 40 through wiring member 60 and terminal block 50. However, output cable 40 may be directly soldered to an end of solar cell 20.

### (Configuration of a Fixture)

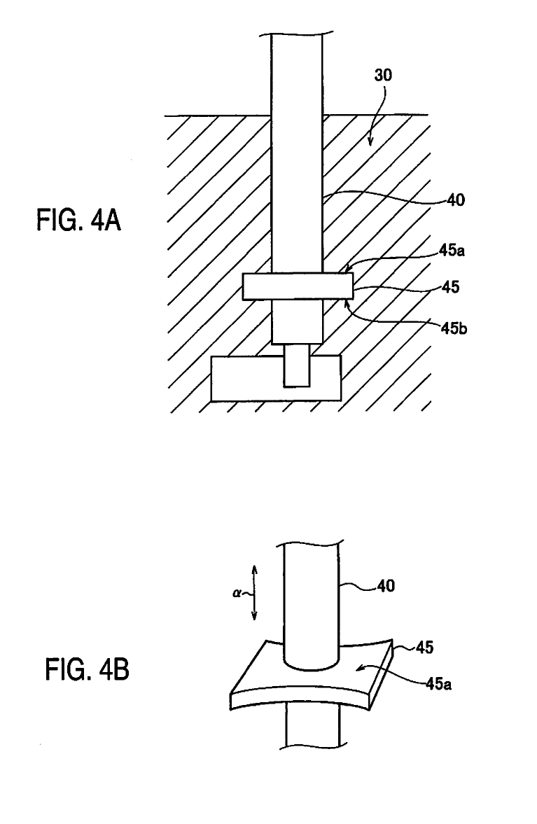

Next, with reference to FIGS. 4A and 4B, a configuration of fixture 45 will be described. FIG. 4A is an enlarged view of a part of FIG. 3. FIG. 4B is a perspective view illustrating an attachment state of fixture 45.

As shown in FIG. 4A, fixture 45 is attached to output cable 40. Fixture 45 has first surface 45a and second surface 45b that is formed in the opposite side to first surface 45a. Fixture 45 is buried in resin constituting case 30. Fixture 45 (to be more specific, first surface 45a and second surface 45b) protrudes from the outer periphery of output cable 40.

Accordingly, as shown in FIG. 4A, fixture 45 is arranged to bite into resin constituting case 30. In other words, the cross-sectional area of fixture 45 in a lateral direction in FIG. 4A is larger than output cable 40.

Fixture 45 is a metal member having a flat-plate shape. As shown in FIG. 4B, fixture 45 is provided with a through-hole formed therein that penetrates from first surface 45a to second surface 45b. When fixture 45 is tightened from both sides with output cable 40 being inserted into the through-hole, fixture 45 is strongly attached to output cable 40. Therefore, first surface 45a and second surface 45b are substantially orthogonal to an extending direction α of output cable 40.

Here, fixture 45 can also be formed by, not limited to a metal member, the same kind of resin as the resin of case 30. Furthermore, fixture 45 may be substantially made of a metal member, or may be substantially made of the resin of case 30.

### (Production Method of a Solar Cell Module)

Firstly, a transparent conductive oxide film is formed on translucent member 10 by a film-forming method, such as a CVD method and a sputtering method. Next, by a CVD method, a semiconductor layer is formed on the transparent conductive oxide film. To be more specific, after layers of p-, i-, and n-type amorphous silicon semiconductors are sequentially laminated on the transparent conductive oxide film, layers of p-, i-, and n-type microcrystal silicon semiconductors are sequentially laminated thereon. Next, by a sputtering method or the like, a back surface electrode is formed on the semiconductor layer.

Note that, in this case, by a commonly-known laser patterning method, this laminated body can be divided into multiple solar cell elements which are electrically serially connected with each other.

Next, one end of a pair of wiring members 60 is soldered to both ends of solar cell 20, and the other end thereof is soldered to terminal block 50.

Next, two output cables 40 including a metal core wire and a insulating film that covers the core wire are prepared. Fixture 45 is fixed to a predetermined position of output cable 40. Next, one end of output cable 40 is soldered to terminal block 50. By this, output cable 40 and solar cell 20 are electrically connected. As described above, a solar cell submodule is prepared.

Next, the solar cell submodule is placed in a predetermined metal mold. Then, a thermoplastic resin is poured into the metal mold, and a pressure of approximately 50 MPa is applied thereto for 30 minutes while applying heat at 150° C. thereto. Thereafter, the metal mold is cooled down, and solar cell module 100 is taken out.

### (Operation and Effect)

Solar cell module 100 of the first embodiment includes solar cell 20, translucent member 10, case 30, and conductive output cable 40 that is buried in case 30. One end of output cable 40 is electrically connected to solar cell 20, and the other end of output cable 40 is exposed to the outside of case 30.

As described above, electric power generated by solar cell 20 is extracted to the outside of solar cell module 100 by output cable 40. Output cable 40 is directly buried in case 30. Accordingly, it is not necessary to attach a terminal box or the like. Therefore, in the production process of solar cell module 100, no complicated assembling work is required.

Meanwhile, output cable 40 is provided with fixture 45 (locking part) configured to lock output cable 40 in case 30. Fixture 45 protrudes from the outer periphery of output cable 40.

As described above, fixture 45 is arranged to bite into resin constituting case 30. Accordingly, even if cable 40 is pulled by an external force, output cable 40 is locked in case 30 by fixture 45. To be more specific, fixture 45 is locked at first surface 45a by resin constituting case 30. Therefore, even in the case where output cable 40 is directly buried in case 30, output cable 40 can be strongly fixed thereto.

### Second Embodiment

Next, a second embodiment will be described. The difference between the second embodiment and the above-described first embodiment is a configuration of the locking part.

In the second embodiment, a schematic configuration of a solar cell module is similar to that of the above-described first embodiment. Therefore, hereinafter, a difference from the first embodiment will be mainly described.

### (Configuration of a Locking Part)

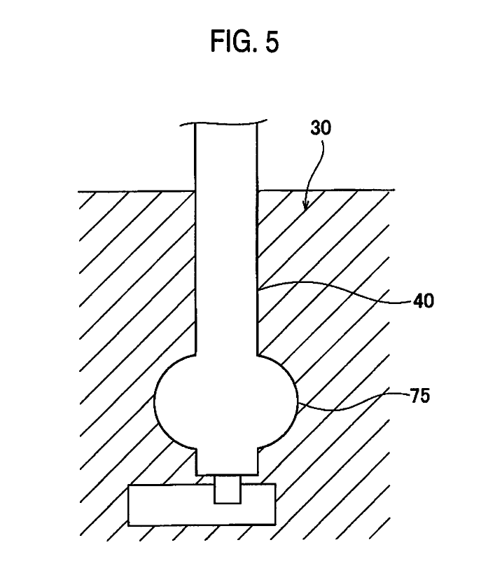

By referring to FIG. 5, a configuration of a locking part will be described. FIG. 5 is a view illustrating a configuration of a spherical part 75 that serves as a locking part of the second embodiment.

As illustrated in FIG. 5, the outside diameter of a part of output cable 40 is formed to be larger than the outside diameter of other part continuous with the part. To be more specific, output cable 40 has spherical part 75, and the outside diameter of spherical part 75 is larger than the outside diameter of a straight line part other than spherical part 75. Spherical part 75 is buried in resin constituting case 30. Accordingly, as shown in FIG. 5, spherical part 75 is arranged to bite into resin constituting case 30.

Such spherical part 75 can be formed by making a part of the insulating film of output cable 40 in a spherical shape. Here, the shape of the core wire in spherical part 75 is not limited.

### (Operation and Effect)

Output cable 40 of the second embodiment is provided with spherical part 75 (locking part) configured to lock output cable 40 in case 30. The outside diameter of spherical part 75 is formed to be larger than the outside diameter of a straight line part continuous with spherical part 75.

As described above, spherical part 75 is arranged to bite into resin constituting case 30. Accordingly, even if output cable 40 is pulled by an external force, output cable 40 is locked in case 30 by spherical part 75. Therefore, even in the case where output cable 40 is directly buried in case 30, output cable 40 can be strongly fixed thereto.

### Modification Example of Second Embodiment

Next, a modification example of the above-described second embodiment will be described. The difference between the modification example and the above-described second embodiment is a configuration of the locking part.

A schematic configuration of a solar cell module in the modification example is also similar to that of the above-described first embodiment. Therefore, hereinafter, a difference from the above-described second embodiment will be mainly described.

### (Configuration of a Locking Part)

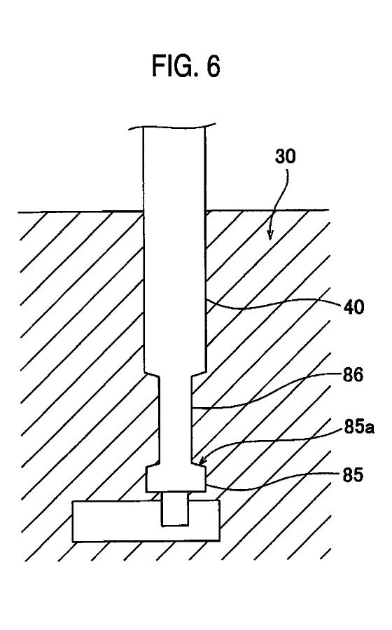

By referring to FIG. 6, a configuration of a locking part will be described. FIG. 6 is a view illustrating a configuration of straight line part 85 that serves as a locking part of the second embodiment.

As illustrated in FIG. 6, the outside diameter of a part of output cable 40 is formed to be larger than the outside diameter of another part continuous with the part. To be more specific, output cable 40 has narrow part 86, and the outside diameter of straight line part 85 is larger than the outside diameter of narrow part 86 continuous with straight line part 85. Accordingly, straight line part 85 has locking surface 85a. Locking surface 85a is the outer circumferential surface that connects straight line part 85 and narrow part 86. Straight line part 85 and narrow part 86 are buried in resin constituting case 30. Accordingly, as shown in FIG. 6, straight line part 85 is arranged to bite into resin constituting case 30.

Such narrow part 86 continuous with straight line part 85 can be formed by making a part of the insulating film of output cable 40 to be thin. Here, the shape of the core wire in narrow part 86 is not limited.

In such a configuration, the outside diameter of a part of output cable 40 is also formed to be larger than the outside diameter of other part continuous with the part. Therefore, similar operation and effect as those in the above-described second embodiment can be obtained.

### Third Embodiment

Next, a third embodiment will be described. The difference between the third embodiment and the above-described first embodiment is a configuration of the locking part.

In the third embodiment, the schematic configuration of a solar cell module is similar to that of the above-described first embodiment. Therefore, hereinafter, a difference from the above-described first embodiment will be mainly described.

### (Configuration of a Locking Part)

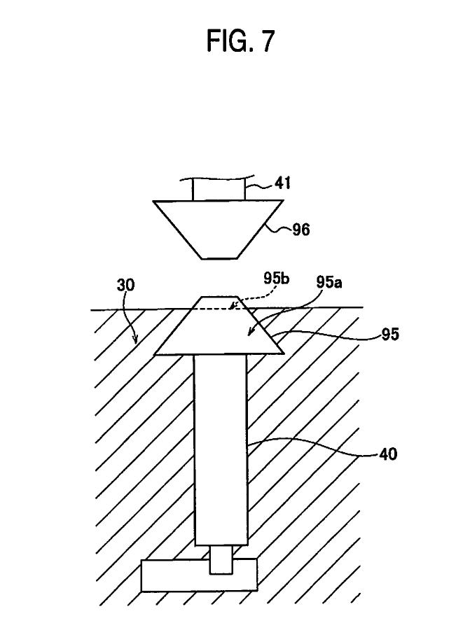

By referring to FIG. 7, a configuration of a locking part will be described. FIG. 7 is a view illustrating a configuration of connecting terminal 95 that serves as a locking part of the third embodiment.

As illustrated in FIG. 7, connecting terminal 95 is formed at one end of output cable 40. Connecting terminal 95 is connected to connecting terminal 96 formed for other output cable 41. Connecting terminal 95 includes first part 95a that is buried in case 30 and second part 95b that is exposed to the outside of case 30.

The outside diameter of first part 95a is formed larger than the outside diameter of second part 95b. Therefore, as shown in FIG. 7, first part 95a is arranged to bite into resin constituting case 30.

### (Operation and Effect)

Output cable 40 of the third embodiment is provided with first part 95a (locking part) configured to lock output cable 40 in case 30. The outside diameter of first part 95a that is buried in case 30 is formed larger than the outside diameter of second part 95b that is exposed to the outside of case 30.

As described above, first part 95a is arranged to bite into resin constituting case 30. Accordingly, even if output cable 41 connected to output cable 40 is pulled by an external force, output cable 40 is locked in case 30 by first part 95a. Therefore, even in the case where output cable 40 is directly buried in case 30, output cable 40 can be strongly fixed thereto.

### Fourth Embodiment

Next, a fourth embodiment will be described. The difference between the fourth embodiment and the above-described first embodiment is a configuration of the locking part.

In the fourth embodiment, a schematic configuration of a solar cell module is similar to that of the above-described first embodiment. Therefore, hereinafter, a difference from the first embodiment will be mainly described.

### (Configuration of a Locking Part)

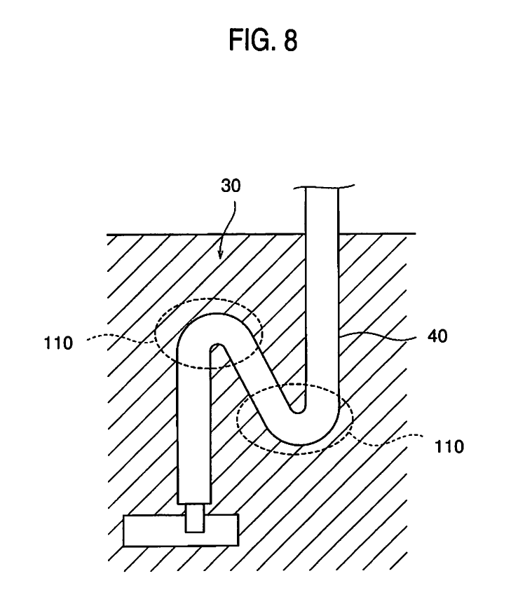

By referring to FIG. 8, a configuration of a locking part will be described. FIG. 8 is a view illustrating a configuration of bent part 110 that serves as a locking part of a fourth embodiment.

As illustrated in FIG. 8, in output cable 40, two bent parts 110 are formed which are bent in case 30.

### (Operation and Effect)

In output cable 40 of the fourth embodiment, two bent parts 110 are formed which are bent in case 30. Accordingly, even if output cable 40 is pulled by an external force, output cable 40 is locked in case 30 by bent parts 110. Therefore, even in the case where output cable 40 is directly buried in case 30, output cable 40 can be strongly fixed thereto.

### Other Embodiments

The present invention can be variously modified without departing from the scope of the above-described embodiments, and descriptions and drawings constituting a part of the present disclosure do not limit the present invention.

For example, in the above-described embodiments, descriptions have been given of an integrated solar cell as an example of solar cell 20. However, solar cell 20 may have a configuration in which multiple solar cell elements are arranged in a matrix pattern. In such a case, it is only required to seal multiple solar cell elements in a sealing member between the transparent protecting member and the back surface side protecting member.

Furthermore, as a solar cell element, a solar cell element that has been commonly known, such as one made of single crystal Si, can be used.

Furthermore, in the above-described first embodiment, fixture 45 having a flat-plate shape is used. However, the shape of fixture 45 is not limited. As long as fixture 45 protrudes from output cable 40, the effect of the invention can be obtained.

Furthermore, in the above-described second embodiment and the modification example thereof, it is only required that the outside diameter of a part of output cable 40 be formed to be larger than the outside diameter of other part continuous with the part. Therefore, the shape of the locking part is not limited.

Furthermore, in the above-described third embodiment, connecting terminal 95 having a conical shape is used as a locking part. However, the shape of connecting terminal 95 is not limited.

Furthermore, in the above-describe fourth embodiment, two bent parts 110 are provided. However, only one bent part 110 may be provided.

As described above, according to the solar cell modules of respective embodiments, a structure for extracting electric power generated by a solar cell can be simplified.

The scope of the invention is indicated by the appended claims rather than by the foregoing description. Hence, all configurations including the meaning and range within equivalent arrangements of the claims are intended to be embraced in the invention.

What is claimed is:

1. A solar cell module comprising:
a solar cell having a light-receiving surface and a back surface formed on an opposite side to the light-receiving surface, the solar cell configured to generate electric power from light on the light-receiving surface;
a translucent member covering the light-receiving surface side of the solar cell;
a case covering the back surface side of the solar cell and formed integrally of a resin; and
a conductive output cable buried in the case, a first end of the output cable electrically connected to the solar cell, a second end of the output cable exposed to the outside of the case, the conductive output cable comprising a locking part that locks the output cable in the case.

2. The module of claim 1, wherein the locking part has a larger diameter than the output cable.

3. The module of claim 2, wherein the locking part has a smaller diameter than the output cable.

4. The module of claim 1, wherein the looking part is a fixture attached to the output cable and protruding from an outer periphery of the output cable.

5. The module of claim 4, wherein the fixture is mainly composed of metal.

6. The module of claim 4, wherein the fixture is mainly composed of the resin.

7. The module of claim 4, wherein the fixture is formed of same resin as the case.

8. The module of claim 1, wherein
the output cable has a connecting terminal attached to the second end, and
the connecting terminal includes a first part that is buried in the case as the locking part and a second part that is exposed to the outside of the case.

9. The module of claim 1, wherein the output cable has a bent locking part.
